(19) United States
(12) Patent Application Publication
(10) Pub. No.: US 2009/0170322 A1
(43) Pub. Date: Jul. 2, 2009

(54) Method for Manufacturing Semiconductor Device Including Vertical Transistor

(75) Inventor: Cheol Kyu Bok, Icheon-si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/164,831

(22) Filed: Jun. 30, 2008

(30) Foreign Application Priority Data
Dec. 31, 2007 (KR) 10-2007-0141517

(51) Int. Cl. H01L 21/308

(52) U.S. Cl. 438/692; 216/41; 257/E21.235

(57) ABSTRACT

A method for manufacturing a semiconductor device including a vertical transistor comprises: depositing a n-layered (here, n is an integer ranging from 2 to 6) mask film over a semiconductor substrate; forming a photoresist pattern over the n-layered mask film; etching the mask film with the photoresist pattern as an etching mask until the m^{th} layer (here, m=n−1) mask film is exposed to form a trench; filling an insulating film in the trench; removing the mask film of the insulating film to form an insulating film pattern; and patterning the m^{th} layer mask film with the insulating film pattern as an etching mask until the semiconductor substrate is exposed.

Priority to Korean Patent Application No. 10-2007-0141517, filed on Dec. 31, 2007, the disclosure of which is incorporated herein by reference, is claimed.

### BACKGROUND

The embodiments relate generally to a method for manufacturing a semiconductor device including a vertical transistor. Specifically, a method comprises: depositing a n-layered (here, n is an integer in a range of 2 to 6) mask film over a semiconductor substrate; forming a photoresist pattern with a contact hole over the n-layered mask film; etching the n-layered mask film with the photoresist pattern as an etching mask until the m^{th} layer (here, m=n−1) mask film is exposed to form a trench; filling an insulating film in the trench; removing the n-layered mask film around the insulating film to form an insulating film pattern; and patterning the m^{th} layer mask film with the insulating film pattern as an etching mask until the semiconductor substrate is exposed.

Due to rapid distribution of information media such as personal portable equipment and personal computers equipped with memory devices, process equipment or process technologies for manufacturing a semiconductor device of high integration having improved reliability and rapid data access speed with large capacity is important.

As the integration of semiconductor memory devices is increased, an area of each unit cell is decreased. Due to reduction of the unit cell area, various methods have been suggested to form a transistor, a bit line, a word line and a filling contact for forming a storage node of a capacitor.

In case of dynamic random access memories (DRAM), a semiconductor device including a vertical channel transistor instead of a planar channel transistor has been developed. In the vertical channel transistor, a source/drain region is not disposed at both sides of a gate. Instead, a vertical extended active pillar pattern is formed over a main surface of a semiconductor substrate. A gate electrode is formed around the pillar pattern. A source/drain region is positioned in upper and lower portions of the active pillar pattern around the gate electrode.

In the vertical channel transistor, since a gate length is determined in a vertical direction, an area of the transistor is reduced, and a channel length does not matter even though the integration is increased. Moreover, the vertical transistor can secure a sufficient channel width using a portion or the whole surface of the gate electrode, thereby improving current characteristics of the transistor.

A semiconductor device including the vertical channel transistor has a buried bit line structure where a line is buried in a device isolating region of a cell. The buried bit line is formed with a self-aligned etching condition of a pillar pattern and an insulating film.

FIGS. 1a to 1c are diagrams illustrating a conventional method for manufacturing a semiconductor device including a vertical transistor.

Referring to FIG. 1 a, a pad oxide film 3 and a deposition mask film 12 are formed over a semiconductor substrate 1. The deposition mask film 12 includes a nitride film 5, an oxide film 7, an amorphous carbon layer 9 and a silicon oxide nitride film 11. An anti-reflection film 13 is deposited over the oxide nitride film 11. A column type photoresist pattern 15 obtained by a photolithography process is formed over the anti-reflection film 13.

Referring to FIG. 1b, the anti-reflection film 13 and the silicon oxide nitride film 11 are etched with the photoresist pattern 15 as an etching mask to form an anti-reflection pattern (not shown) and a silicon oxide nitride film pattern 11-1.

The amorphous carbon layer 9 is also etched with the photoresist pattern 15, an anti-reflection pattern (not shown) and the silicon oxide nitride pattern 11-1 as an etching mask to form an amorphous carbon pattern 9-1. The photoresist pattern 15 and the anti-reflection pattern are removed by the etching process.

Referring to FIG. 1c, the pad oxide film 3, the nitride film 5 and the oxide film 7 are etched with the oxide nitride pattern 11-1 and the amorphous carbon pattern 9-1 as an etching mask to form a pad oxide pattern 3-1, a nitride pattern 5-1 and an oxide pattern 7-1.

The oxide nitride pattern 11-1 is removed by the etching process. An O₂ plasma ashing process is performed on the resulting structure to remove the amorphous carbon pattern 9-1. As a result, a mask pattern for pillar pattern is obtained that includes the pad oxide pattern 3-1, the nitride pattern 5-1 and the oxide pattern 7-1 in the cell array region.

In the conventional method, when a photoresist pattern used as the etching mask pattern is formed, light penetrates from all directions, thereby increasing the proximity effect due to diffraction to degrade an illusory image contrast. As a result, the resolution and line-width uniformity of the photoresist pattern are decreased.

A general photolithography process for forming a photoresist pattern includes an exposure step, a developing step, a rinsing step and dehydrating step. After the rinsing step, distilled water is evaporated while a wafer is revolved to be dehydrated. As a result, the attraction between the patterns increases and overcomes the adhesive power and mechanical strength of the photoresist pattern to the semiconductor substrate, thereby collapsing the photoresist pattern. As a result, it is difficult to remove the photoresist pattern with the line-width uniformly when a subsequent pillar pattern is formed.

### SUMMARY

Disclosed herein is a method for manufacturing a semiconductor device including a vertical transistor, which can prevent collapse of a photoresist pattern.

According to an embodiment, a method for manufacturing a semiconductor device including a vertical transistor comprises: depositing a n-layered (here, n is an integer in a range of 2 to 6) mask film over a semiconductor substrate; forming a photoresist pattern with a contact hole over the n-layered mask film; etching the n-layered mask film with the photoresist pattern as an etching mask until the m^{th} layer (here, m=n−1) mask film is exposed to form a trench; filling an insulating film in the trench; removing the n-layered mask film around the insulating film to form an insulating film pattern; and patterning the m^{th} layer mask film with the insulating film pattern as an etching mask until the semiconductor substrate is exposed.

The contact hole and the insulating film pattern preferably have same line-width as that of a subsequent pillar pattern.

The n-layered mask film preferably includes a nitride film, a mask oxide film, a polysilicon film, an amorphous carbon layer and a silicon oxide nitride film.

Forming a trench is preferably performed with an etching gas including O₂ and one selected from the group consisting of CF₄, CHF₃, N₂, HBr and Cl₂.

Filling an insulating film preferably includes: depositing an insulating film over the resulting structure including the trench; and planarizing the insulating film until the n-layered mask film is exposed.

The insulating film preferably has a different material from that of the n-layered mask film.

The insulating film can include a spin-on carbon layer or one or more of a HDP oxide film, a PE-TEOS oxide film, a BPSG oxide film and a PSG oxide film. The spin-on carbon layer preferably includes a carbon-rich polymer containing a carbon in the range of 85 to 90 wt %.

Planarizing is preferably performed by an etch-back process or a CMP process.

Removing the n-layered mask film around the insulating film is preferably performed by immersing the substrate in a solution including ammonia water, nitric acid and HF.

Patterning the m^{th} layer mask film step is preferably performed with an etching gas including one or more of CF₄, CHF₃ and O₂.

The method may further comprise forming a pad oxide film over the semiconductor substrate.

### BRIEF DESCRIPTION OF THE DRAWINGS

For a more complete understanding of the disclosure, reference should be made to the following detailed description and accompanying drawings.

FIGS. 1a to 1c are diagrams illustrating a conventional method for manufacturing a semiconductor device including a vertical transistor.

FIGS. 2a to 2h are diagrams illustrating a method for manufacturing a semiconductor device including a vertical transistor.

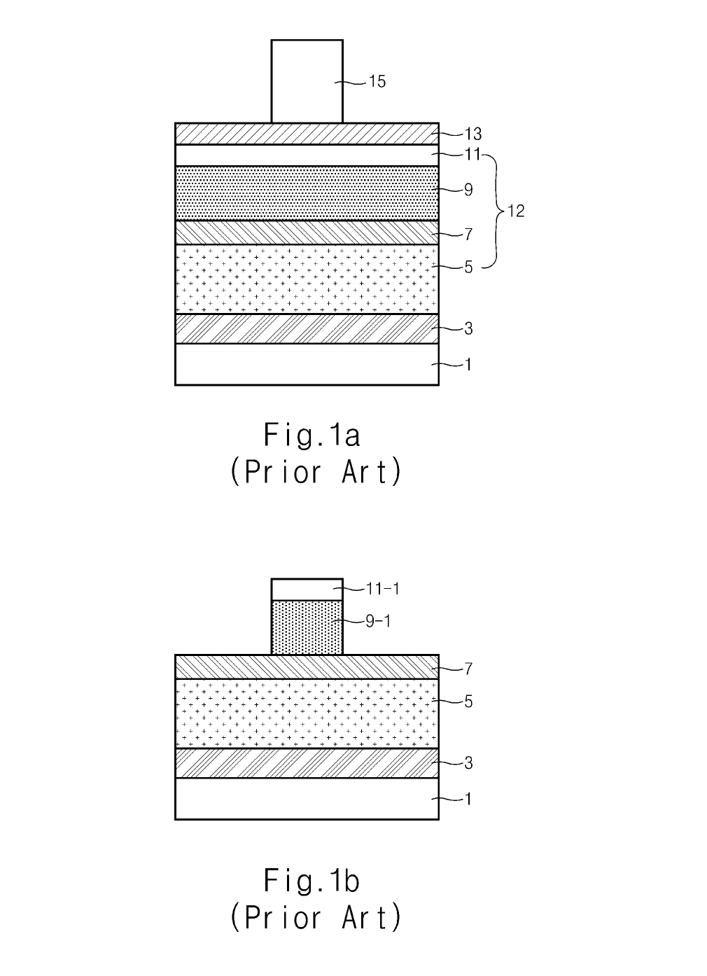

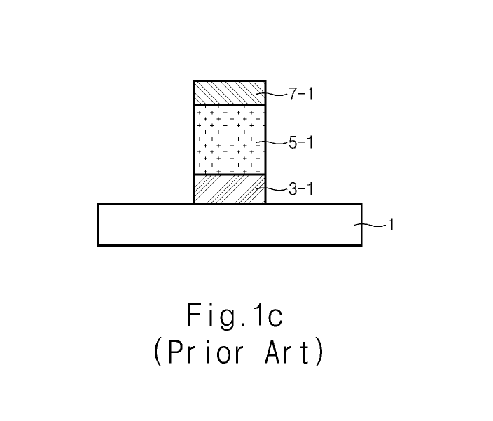

While the disclosed method is susceptible of embodiments in various forms, specific embodiments are illustrated in the drawings (and will hereafter be described), with the understanding that the disclosure is intended to be illustrative, and is not intended to limit the invention to the specific embodiments described and illustrated herein.

### DETAILED DESCRIPTION

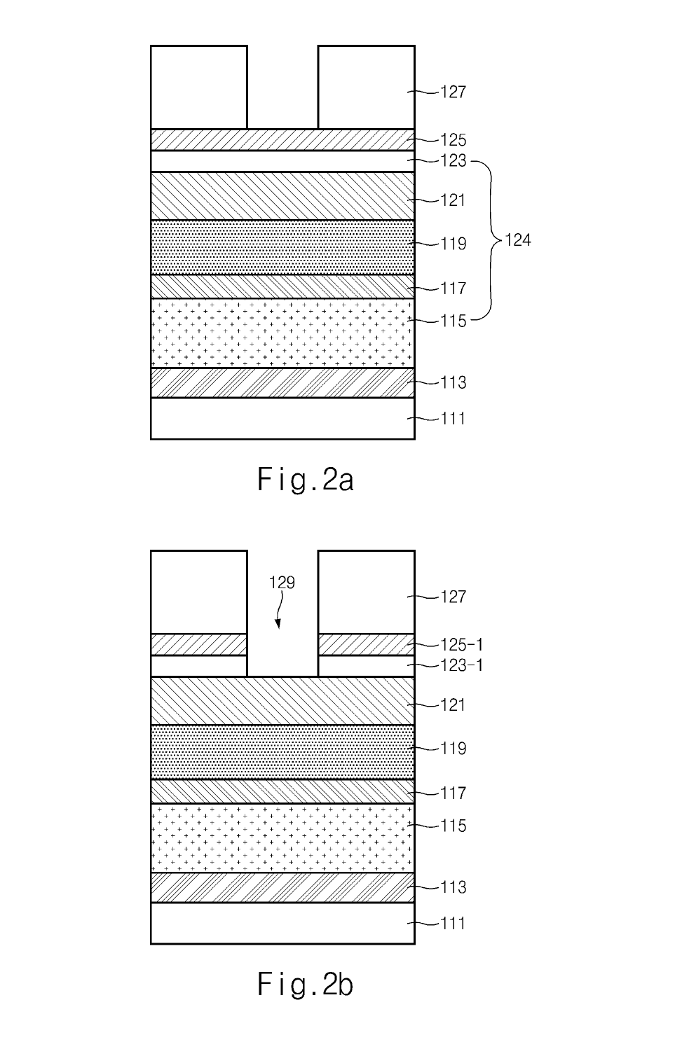

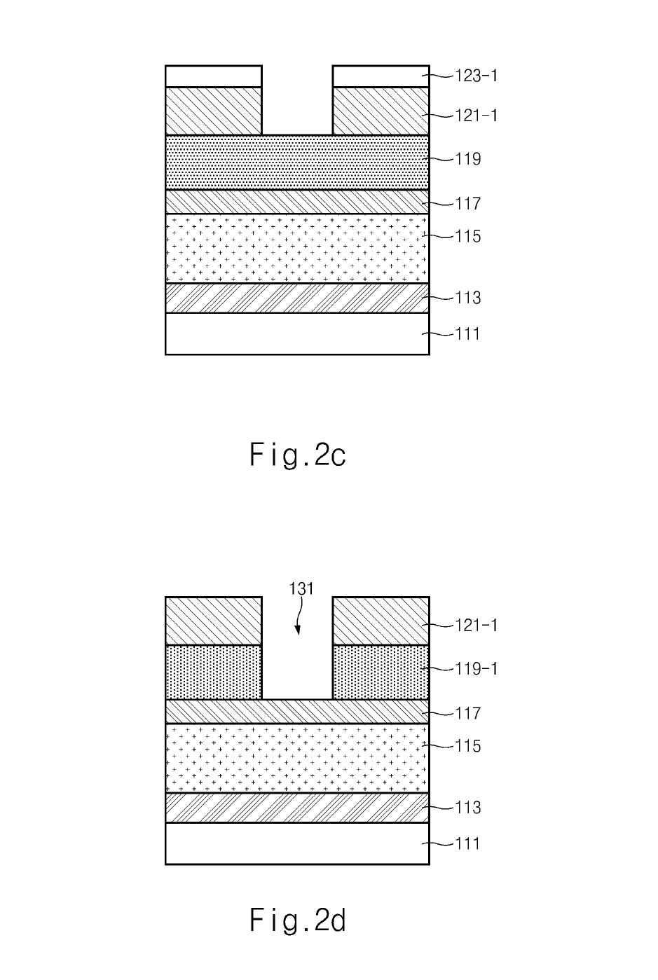

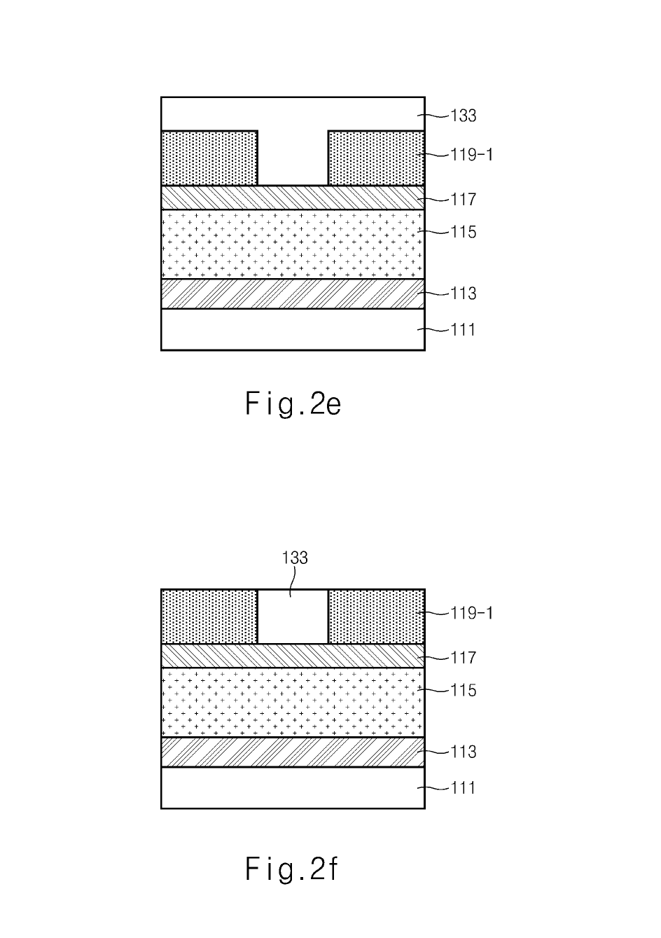

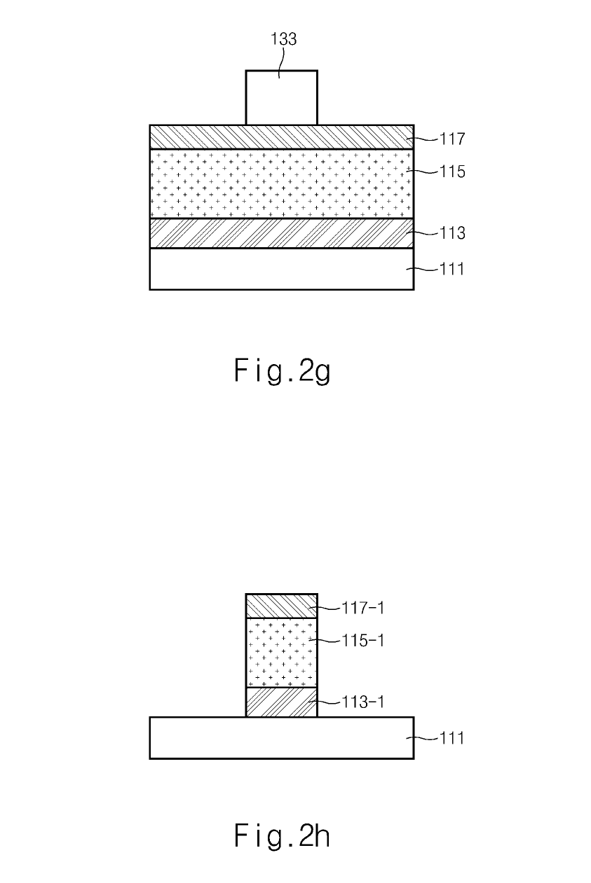

FIGS. 2a to 2h are diagrams illustrating a method for manufacturing a semiconductor device including a vertical transistor. Referring to FIG. 2a, a pad oxide film 113 and a n-layered (here, n is an integer in a range of 2 to 6) mask film 124 are deposited over a semiconductor substrate 111.

The pad oxide film 113 is formed to have a thickness in a range of about 40 to 60 Å, preferably 50 Å.

The n-layered mask film 124 includes a nitride film 115, a mask oxide film 117, a polysilicon film 119, an amorphous carbon layer 121 and a silicon oxide nitride film 123. Preferably, the mask film 124 includes the nitride film 115 having a thickness of about 1,500 Å, the mask oxide film 117 having a thickness of about 500 Å, the polysilicon film 119 having thickness of about 1,500 Å, the amorphous carbon layer 121 having thickness of about 1,500 Å and the silicon oxide nitride film 123 having a thickness of about 300 Å.

An anti-reflection film 125 and a photoresist film (not shown) are formed, e.g., sequentially, over the mask film 124.

For example, the anti-reflection film (ARC93 produced by Nissan Co. or DARC-440 produced by Dongjin Semichem Co.) preferably has a thickness of 280 Å and is baked at 240° C. The photoresist film (KIT-07C produced by Keumho Petrochemical Co.) preferably has a thickness in a range of 1,000 to 1,200 Å and is baked at 115° C. for 90 seconds.

A photolithography process can be performed on the photoresist film (not shown) to form a photoresist pattern 127 including a contact hole 129.

The photolithography process can be any general method for forming a photoresist pattern, which is not limited.

Referring to FIG. 2b, the anti-reflection film 125 and the silicon oxide nitride film 123 are patterned with the photoresist pattern 127 including the contact hole 129 as an etching mask, thereby forming a deposition pattern including a silicon oxide nitride pattern 123-1, an anti-reflection pattern 125-1 and a photoresist pattern 127.

The patterning process can be performed using etching equipment (Kiyo45 produced by RAM Co., or SPS2 produced by AMAT Co.) under a condition in a range of 5-20 mT and a source power in a range of 300 to 1,500 W with an etching gas including one or more of CF₄ in a range of 20 to 100 sccm, CHF₃ in a range of 10 to 50 sccm and O₂ in a range of 3 to 120 sccm.

Referring to FIG. 2c, the amorphous carbon layer 121 is patterned with the deposition pattern as an etching mask to form an amorphous carbon pattern 121-1.

The patterning process can be performed using etching equipment (Kiyo45 produced by RAM Co., or SPS2 produced by AMAT Co.) under a condition in a range of 5-20 mT and a source power in a range of 400 to 6,000 W with an etching gas including one or both of O₂ in a range of 90 to 110 sccm and N₂ in a range of 7 to 90 sccm.

The anti-reflection pattern 125-1 and the photoresist pattern which are used as the etching mask preferably are removed during the patterning process, so that an additional removing process is not necessary.

Referring to FIG. 2d, the polysilicon layer 119 is patterned with the amorphous carbon pattern 121-1 as an etching mask to form a polysilicon pattern 119-1 including a trench 131.

The patterning process can be performed using etching equipment (Kiyo45 produced by RAM Co., or SPS2 produced by AMAT Co.) under a condition in a range of 5-20 mT and a source power in a range of 500 to 15,000 W with an etching gas including one or more of HBr in a range of 100 to 300 sccm, Cl₂ in a range of 10 to 100 sccm and O₂ in a range of 90 to 110 sccm.

Referring to FIG. 2e, an insulating film is deposited over the polysilicon pattern 119-1 including the trench 131.

The insulating film 133 can include a spin-on carbon layer 133 or one or more if a high density plasma (HDP) oxide film, a plasma enhanced tetraethoxysilicate glass (PE-TEOS) oxide film, a borophosphosilicate glass (BPSG) oxide film and a phosphosilicated glass (PSG) oxide film, which have a different physical property about etching selectivity from that of the deposition mask forming material. The spin-on carbon layer 133 is a coatable compound by a simple spin coating method, for example, a carbon rich polymer containing a carbon ingredient in a range of 85 to 90 wt % based on the total compound. In order to obtain the spin-on carbon layer, a composition containing a carbon-rich polymer is coated to a thickness in a range of 1,000 to 2,000 Å, and baked at 180-220 Å for 90 seconds. As the composition containing the carbon-rich polymer, NCA9018 produced by Nissan Co. or ULX138 produced by Shinetsu Co can be used.

Referring to FIG. 2f, the spin-on carbon layer 133 is planarized to the polysilicon pattern 119-1. The planarization process can be performed by an etch-back or CMP process.

The patterning process can be performed using etching equipment (Kiyo45 produced by RAM Co., or SPS2 produced by AMAT Co.) under a condition in a range of 5-20 mT and a source power in a range of 400 to 6,000 W with an etching gas including one or both of O₂ in a range of 90 to 110 sccm and N₂ in a range of 70 to 90 sccm.

Referring to FIG. 2g, after the planarization process of FIG. 2f, the polysilicon pattern 119-1 is removed to form a column-type mask pattern including the spin-on carbon layer 133.

The wafer is preferably immersed in about 20-30% ammonia aqueous solution and a mixture solution including nitric acid and HF for about 10-100 seconds to remove the polysilicon pattern 119-1.

As a result, a spin-on carbon pattern is formed which has the same line-width as that of the contact hole of the photoresist pattern. An image reversal process can be performed to change a pattern shape.

Referring to FIG. 2h, the pad oxide film 113, the nitride film 115 and the mask oxide film 117 are etched with the spin-on carbon pattern 133 of FIG. 2g as an etching mask to the semiconductor substrate 111, thereby obtaining a deposition pattern including a pad oxide pattern 113-1, a nitride pattern 115-1 and a mask oxide pattern 117-1.

The spin-on carbon pattern is preferably removed by the etching process. As a result, an additional removing process is not required.

The patterning process can be performed using etching equipment (Flex45 produced by RAM Co., or eMAX produced by AMAT Co.) under a condition in a range of 5-20 mT and a source power in a range of 500 to 1,500 W with an etching gas including one or more of CF₄ in a range of 50 to 200 sccm, CHF₃ in a range of 30 to 150 sccm and O₂ in a range of 5 to 20 sccm.

As a result, a deposition mask pattern for pillar pattern used in a process for manufacturing a vertical transistor is obtained.

As described above, according to an embodiment, a mask pattern for pillar pattern is formed with a photoresist pattern including a contact hole, thereby preventing collapse of the photoresist pattern. As a result, a stable subsequent process for forming a pillar pattern can be performed. Moreover, while a photolithography process for forming the contact hole is performed, the thickness of the photoresist pattern is not damaged, so that the photoresist pattern can serve as an etching mask in a subsequent etching process, thereby facilitating line-width control of lower layers. When the photoresist pattern including the contact hole is used as a mask pattern for a pillar pattern, a pillar pattern can be obtained with improved resolution and line-width uniformity. When a pillar pattern is formed with the photoresist pattern including the contact hole, the contact hole is changed with a column-type photoresist pattern to increase a depth of focus (DOF) margin, thereby reducing the pattern defect ratio due to defocus and improving device yield.

It should be understood that numerous other modifications and embodiments fall within the spirit and scope of the principles of this disclosure. More particularly, a number of variations and modifications are possible in the component parts and/or arrangements within the scope of the disclosure, the drawings and the appended claims. In addition to variations and modifications in the component parts and/or arrangements, alternative uses will also be apparent to those skilled in the art.

What is claimed is:

1. A method for manufacturing a semiconductor device including a vertical transistor comprising:
depositing a n-layered mask film over a semiconductor substrate, wherein n is an integer in a range of 2 to 6;
forming a photoresist pattern with a contact hole over the n-layered mask film;
etching the n-layered mask film with the photoresist pattern as an etching mask until a m^{th} layer of the mask film is exposed to form a trench, wherein m=n−1;
filling an insulating film in the trench;
removing the n-layered mask film around the insulating film to form an insulating film pattern; and
patterning the m^{th} layer mask film with the insulating film pattern as an etching mask until the semiconductor substrate is exposed.

2. The method according to claim 1, further comprising forming a subsequent pillar pattern having the same line-width as the contact hole and the insulating film pattern.

3. The method according to claim 1, wherein the n-layered mask film comprises a nitride film, a mask oxide film, a polysilicon film, an amorphous carbon layer and a silicon oxide nitride film.

4. The method according to claim 1, comprising forming the trench with an etching gas comprising O₂ and one selected from the group consisting of CF₄, CHF₃, N₂, HBr and Cl₂.

5. The method according to claim 1, comprising filling the insulating film by:
depositing an insulating film over the resulting mask film structure including the trench; and
planarizing the insulating film until the n-layered mask film is exposed.

6. The method according to claim 5, wherein the insulating film comprises a different material from that of the n-layered mask film.

7. The method according to claim 5, wherein the insulating film comprises a spin-on carbon layer.

8. The method according to claim 7, wherein the spin-on carbon layer comprises a carbon-rich polymer containing a carbon in a range of 85 to 90 wt %.

9. The method according to claim 6, wherein the insulating film comprises one or more of a HDP oxide film, a PE-TEOS oxide film, a BPSG oxide film and a PSG oxide film.

10. The method according to claim 5, comprising planarizing the insulating film by an etch-back process and a CMP process.

11. The method according to claim 1, comprising removing the n-layered mask film around the insulating film by immersing the semiconductor device in a solution comprising ammonia, water, nitric acid and HF.

12. The method according to claim 1, comprising patterning the m^{th} layer mask film with an etching gas comprising CF₄, CHF₃ and O₂.

13. The method according to claim 1, further comprising forming a pad oxide film over the semiconductor substrate.
